(19) United States
(12) Patent Application Publication
(10) Pub. No.: US 2007/0268660 A1
(43) Pub. Date: Nov. 22, 2007

(54) SPACERLESS SEMICONDUCTOR PACKAGE CHIP STACKING SYSTEM

(75) Inventors: Seungyun Ahn, Ichon-si (KR); Youngcheol Kim, Young In-si (KR); Haengcheol Choi, Gyo-ri (KR); Myung Kil Lee, Seoul (KR); JoHyun Bae, Seoul (KR); Hyunil Bae, Nonsan-si (KR); Junwoo Myung, Jinhae-si (KR)

Correspondence Address: ISHIMARU & ZAHRT LLP, 333 W. EL CAMINO REAL, SUITE 330, SUNNYVALE, CA, 94087, US

(73) Assignee: STATS CHIPPAC LTD., Singapore (SG)

(21) Appl. No.: 11/383,802

(22) Filed: May 17, 2006

(51) Int. Cl. H05K 5/00

(52) U.S. Cl. 361/683

(57) ABSTRACT

A spacerless semiconductor package chip stacking system is provided having a substrate. The substrate has at least one window therethrough. A first semiconductor device is attached face down on the top of the substrate. A second semiconductor device is attached face up on the back of the first semiconductor device. The first semiconductor device is electrically connected through the window to the bottom of the substrate. The second semiconductor device is electrically connected to the substrate.

### TECHNICAL FIELD

The present invention relates generally to semiconductor technology, and more particularly to an integrated circuit spacerless semiconductor package chip stacking system.

### BACKGROUND ART

Important and constant goals of the computer industry include higher performance, lower cost, increased miniaturization of components, and greater packaging density for integrated circuits (“ICs”). As new generations of IC products are released, the number of IC devices needed to fabricate them tends to decrease due to advances in technology. Simultaneously, the functionality of these IC products increases. For example, on the average there is approximately a 10 percent decrease in components required for every IC product generation over a previous generation having equivalent functionality.

Semiconductor package structures continue to become thinner and ever more miniaturized. This results in increased component density in semiconductor packages and decreased sizes of the IC products in which the packages are used. These developmental trends are in response to continually increasing demands on electronic apparatus designers and manufacturers for ever-reduced sizes, thicknesses, and costs, along with continuously improving performance.

These increasing requirements for miniaturization are particularly noteworthy, for example, in portable information and communication devices such as cell phones, hands-free cell phone headsets, personal data assistants (“PDA's”), camcorders, notebook personal computers, and so forth. All of these devices continue to be made smaller and thinner to improve their portability. Accordingly, large-scale IC (“LSI”) packages incorporated into these devices, as well as the package configurations that house and protect them, must also be made smaller and thinner.

Many conventional semiconductor chip or die packages are of the type where a semiconductor chip is molded into a package with a resin, such as an epoxy molding compound. The packages have a leadframe whose out leads are projected from the package body to provide a path for signal transfer between the chip and external devices. Other conventional package configurations have contact terminals or pads formed directly on the surface of the package.

In IC packaging, in addition to component size reduction, surface mount technology (“SMT”) has demonstrated an increase in semiconductor chip density on a single substrate (such as a printed circuit board (“PCB”)) despite the reduction in the number of components. SMT is a method used to connect packaged chips to substrates. With SMT, no through-holes in the substrate are required. Instead, package leads are soldered directly to the substrate surface. This results in more compact designs and form factors, and a significant increase in IC density and performance. However, despite these several reductions in size, IC density continues to be limited by the space or “real estate” available for mounting chips on a substrate.

One method to further increase IC density is to stack semiconductor chips vertically. Multiple stacked chips can be combined into a single package in this manner with a very small surface area or “footprint” on the PCB or other substrate. In many cases, however, this requires customized chip configurations.

Therefore, it would be advantageous to develop a stacking solution and assembly configuration for increasing IC density using non-customized (i.e., standard) chip configurations with commercially-available, widely-practiced semiconductor device fabrication techniques. This is ever more critical as the semiconductor industry continues to demand semiconductor devices with lower costs, higher performance, increased miniaturization, and greater packaging densities. Substantially improved system-in-package (“SiP”) solutions are thus greatly needed to address these requirements.

Typically, a SiP is assembled in a multi-chip module (“MCM”) format, wherein the stacked chip packaging technologies have made it possible to even further reduce the substrate size for chip attachment. However, while the footprint of the package is reduced by stacking the chips vertically with respect to each other, the height of the package is increased as a result. In fact, the height increases more than simply the sum of the individual heights of the individual semiconductor chips. The extra height is caused by the need to electrically connect the individual chips within the package without interfering with each other.

In one previous technique, for example, a dummy device, such as a dummy semiconductor chip, is interposed between first and second active or “real” semiconductor chips. The resulting configuration is then comprised of a first semiconductor chip attached to the substrate, a dummy chip on the first semiconductor chip, and a second semiconductor chip stacked atop the dummy chip. Additional spacing between the chips may be provided by adhesive layers that bond the chips to one another and to the substrate.

The spacing is necessary to provide clearance between the first and second chips for the various bonding wires that are formed into loops that connect the first and second semiconductor chips to the substrate. The clearance prevents the bonding wire loops from inadvertently contacting the chips.

Unfortunately, however, the additional height caused by the dummy chip and by the additional epoxy or other adhesive layer for the dummy chip causes the package to have a higher package profile than is desired. The additional height also incurs more process assembly time and product failure risk.

Another previous technique employs a filler adhesive interposed between the first and second chips. The filler adhesive contains mono-sized fillers that impose a spacing between the chips according to the size of the filler particles. The mono-sized filler adhesive has the advantage that the first and second chips can be spaced more closely to each other. Another advantage is that less process time is needed than when a dummy chip is used to provide the spacing. The advantages result in a lower package profile and lower costs. However, the mono-sized filler adhesive requires careful filler size stabilization, and can present difficulties in die attach quality control, epoxy wetting, die tilt, and other process complications.

Yet another previous technique employs mono-sized filler adhesives with smaller mono-sized fillers, further reducing the overall package height. To control the risk of contact between the bonding wires and the chips with such a reduced inter-chip spacing, a non-conductive film can be inserted directly beneath the upper or second chip and above the smaller mono-sized filler adhesive.

In still another previous technique, a film adhesive spacer of appropriate thickness may be utilized rather than a dummy device or a mono-sized filler adhesive.

Other previous techniques have been attempted, such as, for example, using non-standard or customized chip configurations in which the bonding pads on the chips are carefully located and the chips are configured to allow them to be stacked atop one another. For example, oblong chips with the bonding pads at the farthest ends have been stacked in a crisscross fashion atop one another. Or a pyramidal stack of progressively smaller chips has been utilized with, or as an alternative to, such a crisscross configuration.

Similarly, centrally located bonding pads have sometimes been used. However, this can significantly complicate the design of the chips, and can result in signal loss problems due to long signal traces within the chips, long bonding wires, and so forth.

In these and other previous techniques, complimentary, extended length signal traces within the substrate have oftentimes been similarly necessary to connect to external package contacts such as ball grid array (“BGA”) or pin grid array (“PGA”) configurations.

Thus, a need still remains for smaller, thinner, lighter, less-expensive IC multi-chip modules, and particularly such multi-chip modules that can readily accommodate and stack standard chips. In view of the ever-increasing commercial competitive pressures, along with growing consumer expectations and the diminishing opportunities for meaningful product differentiation in the marketplace, it is critical that answers be found for these problems. Additionally, the need to save costs, improve efficiencies and performance, and meet competitive pressures, adds an even greater urgency to the critical necessity for finding answers to these problems.

Solutions to these problems have been long sought but prior developments have not taught or suggested any solutions and, thus, solutions to these problems have long eluded those skilled in the art.

### DISCLOSURE OF THE INVENTION

The present invention provides a spacerless semiconductor package chip stacking system. A substrate is provided having at least one window therethrough. A first semiconductor device is attached face down on the top of the substrate. A second semiconductor device is attached face up on the back of the first semiconductor device. The first semiconductor device is electrically connected through the window to the bottom of the substrate. The second semiconductor device is electrically connected to the substrate.

Certain embodiments of the invention have other aspects in addition to or in place of those mentioned above. The aspects will become apparent to those skilled in the art from a reading of the following detailed description when taken with reference to the accompanying drawings.

### BRIEF DESCRIPTION OF THE DRAWINGS

FIG. 1 is a top view of a substrate in accordance with an embodiment of the present invention;

FIG. 2 is a bottom view of a package formed using the substrate shown in FIG. 1;

FIG. 3 is a top view representation of a wafer diced into individual chips;

FIG. 4 is a top view representation of a diced, inverted tape-mounted wafer;

FIG. 5 shows an embodiment of a substrate similar to the substrate shown in FIG. 1;

FIG. 6 is a view of the first step of a first process for assembling the substrate shown in FIG. 5 and the chips shown in FIGS. 3 and 4 into a package such as shown in FIG. 14;

FIG. 7 is a view of the second step of the first process of FIG. 6;

FIG. 8 is a view of the first step of an alternative process similar to that of FIGS. 6 and 7;

FIG. 9 is a cross-sectional view of the structure of FIG. 4 with film adhesive applied to a chip;

FIG. 10 is the structure of FIG. 9 following retrieval of chips from the diced wafers by a vacuum picker;

FIG. 11 is the structure of FIG. 8 after transportation to it of the chips by the vacuum picker;

FIG. 12 shows a first wire attach stage for the structures shown in FIGS. 7 and 11;

FIG. 13 shows a second wire attach stage following the stage shown in FIG. 12;

FIG. 14 is the structure of FIG. 13 encapsulated into a package;

FIG. 15 is a view of a package similar to the package of FIG. 14 but having a larger upper chip;

FIG. 16 is a view of a package similar to FIGS. 14 and 15 but having a smaller upper chip;

FIG. 17 is a view of a package similar to the package of FIG. 14 with additional chips of progressively smaller sizes mounted on top;

FIG. 18 is a view of a substrate similar to the substrate of FIG. 1 but with four windows and with bonding pads on four sides of the bottom of the substrate;

FIG. 19 is a bottom view of a package formed using the substrate shown in FIG. 18; and

FIG. 20 is a flow chart of a system 2000 for spacerless semiconductor package chip stacking in accordance with an embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that process or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail.

Likewise, the drawings showing embodiments of the system are semi-diagrammatic and not to scale and, particularly, some of the dimensions are for the clarity of presentation and are shown greatly exaggerated in the drawing FIGS. Similarly, although the views in the drawings for ease of description generally show similar orientations, this depiction in the FIGS. is arbitrary for the most part. Generally, the invention can be operated in any orientation.

In addition, where multiple embodiments are disclosed and described having some features in common, for clarity and ease of illustration, description, and comprehension thereof, similar and like features one to another will ordinarily be described with like reference numerals.

For expository purposes, the term “horizontal” as used herein is defined as a plane parallel to the plane or surface of the integrated circuit package substrate, regardless of its orientation. The term “vertical” refers to a direction perpendicular to the horizontal as just defined. Terms, such as “on”, “above”, “below”, “bottom”, “top”, “side” (as in “sidewall”), “higher”, “lower”, “upper”, “over”, and “under”, are defined with respect to the horizontal plane. The term “processing” as used herein includes deposition of material or photoresist, patterning, exposure, development, etching, cleaning, and/or removal of the material or photoresist as required in forming a described structure.

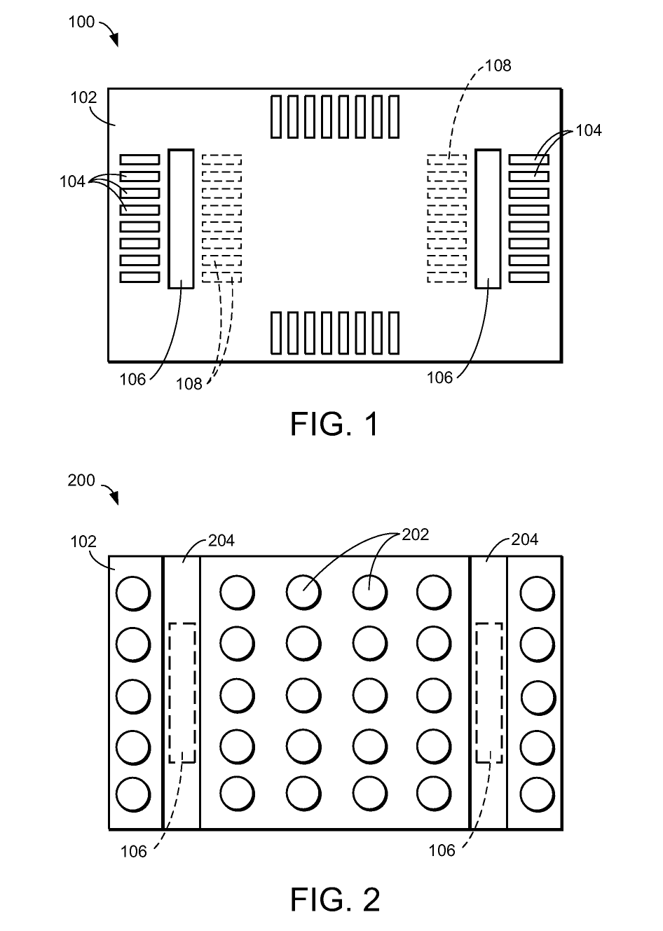

Referring now to FIG. 1, therein is shown a top view of a substrate 100 according to an embodiment of the present invention. The substrate 100 makes it possible to conveniently and economically stack multiple chips without requiring spacers between the chips even when the chips have the same or similar sizes. This not only eliminates the need for chips that are custom designed to have a special configuration, but it also eliminates the additional process time and process control difficulties, as well as the additional components, needed to prevent the bonding wires from unintentionally contacting the chips.

The substrate 100 includes a board 102, such as a printed circuit board (“PCB”). In this embodiment, top bonding pads 104 are provided along the sides of the board 102. Windows 106, for wire bonding, are provided through the board 102 adjacent bottom bonding pads 108 on the side of the board 102 opposite the top bonding pads 104. As will be described later (see, for example, FIG. 13), the windows 106 are openings through the board 102 that are sized and positioned to be located and aligned facing the bonding pads on a semiconductor chip that will be secured adjacent thereto.

Referring now to FIG. 2, therein is shown a bottom view of a package 200 formed using the substrate 100 (FIG. 1). Solder balls 202 are attached to the bottom of the package 200 in a ball grid array (“BGA”) configuration, and it will be understood that other suitable interfaces, such as a pin grid array (“PGA”), may similarly be provided on the bottom of the package 200. The windows 106 have been sealed and encapsulated in a lower encapsulation portion 204 (or transfer mold) similar to that illustrated, for example, in FIG. 14.

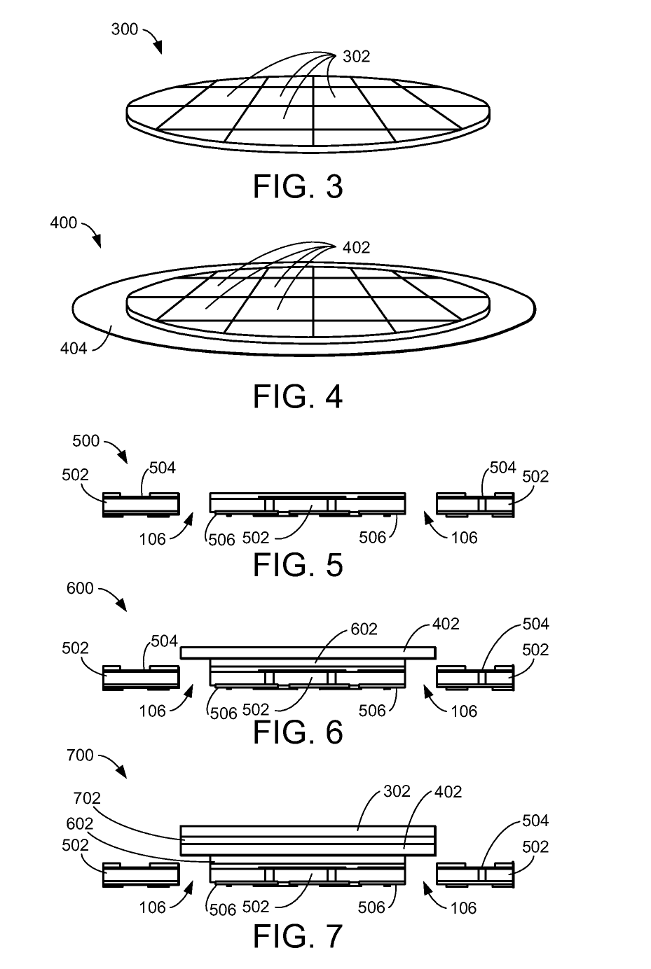

Referring now to FIG. 3, therein is shown a top view representation of a wafer 300 that has been diced (e.g., sawed) into individual chips 302.

Referring now to FIG. 4, therein is shown a top view representation of an inverted tape-mounted wafer 400 that has also been diced into individual chips 402. The chips 402 are mounted in an inverted or face down position on a wafer mount tape 404. The chips 402 may be the same type of chips as the chips 302 (FIG. 3) or different chips. As will be described subsequently, the chips 402 will be mounted in this inverted position directly onto a substrate (e.g., the substrates shown in FIGS. 1 or 5), and the chips 302 will then be mounted directly onto the sides of the chips 402 opposite the substrate.

Referring now to FIG. 5, therein is shown an embodiment 500 of a substrate similar to the substrate 100 shown in FIG. 1. The embodiment 500 includes a board 502, such as a PCB. Top bonding pads 504 are provided on the top of the board 502. Bottom bonding pads are provided on the bottom of the board 502 adjacent windows 106 that pass through the board 502.

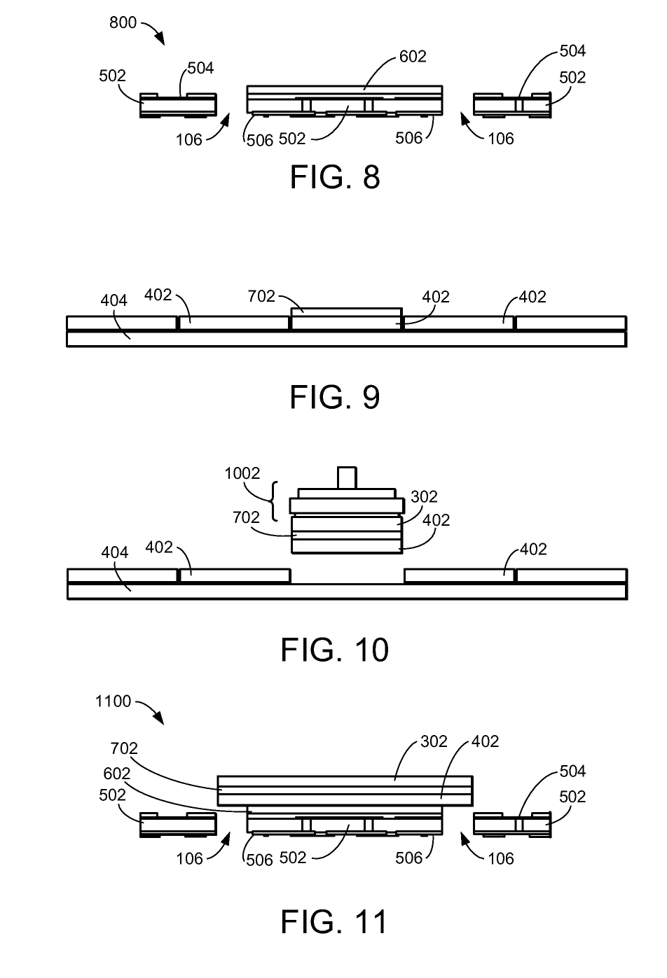

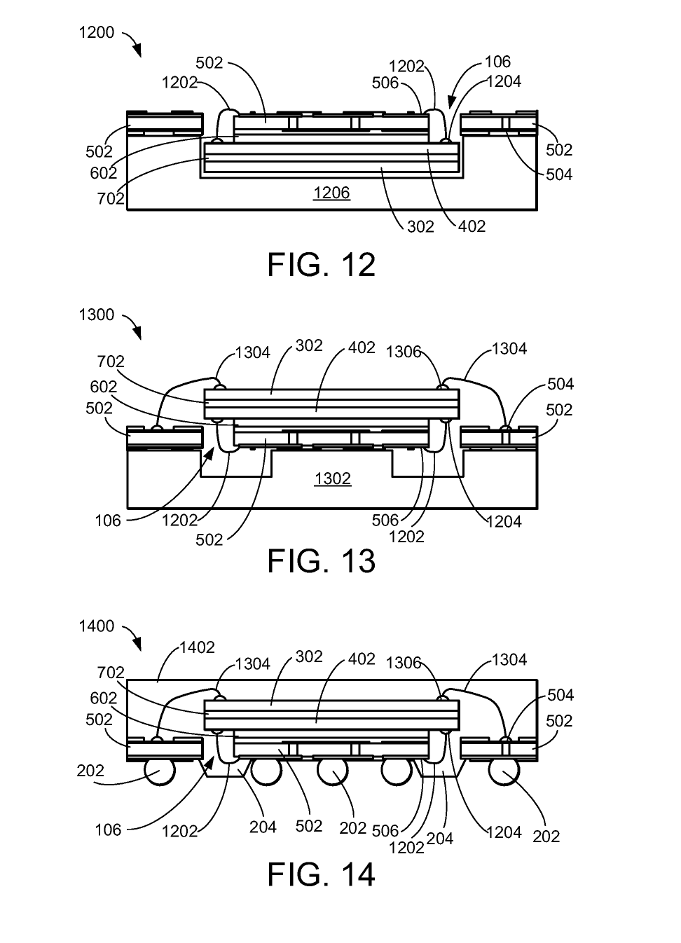

Steps will now be described for assembling the chips 302 (FIG. 3) and the chips 402 (FIG. 4) with the board 502 (FIG. 5) into a package such as the package 1400 shown in FIG. 14. Two different processes or procedures will be described leading to the same package 1400. The final stages of these processes, illustrated in FIGS. 12-14, are the same. The initial stages are somewhat different, the initial stages for the first process being illustrated in FIGS. 6 and 7, and the initial stages for the second process being illustrated in FIGS. 8-11.

Referring now to FIG. 6, therein is shown the first step 600 of the first process. A pre-applied adhesive (“PAA”) 602 has been attached to the top of the board 502 and is laminated thereto. A chip 402 has been attached in the face down position to the PAA 602 on the top of the board 502. The PAA 602 is then cured. (In this process, the wafer mount tape 404 (FIG. 4) is optional and may be omitted.)

Referring now to FIG. 7, therein is shown the second step 700 of the first process. A chip 302 (FIG. 3) has been attached face up to the structure of FIG. 6, on the back of the chip 402, by a film adhesive 702. The film adhesive 702 may be applied, for example, by cutting and placing it on the chip 302 or by laminating it on the backside of the chip 402. The film adhesive 702 is then cured.

As thus assembled, the chip 302 is upright or face up, the chip 402 is inverted or face down, and the chip 302 is attached face up on the back of the chip 402.

The first process then continues as described hereinbelow with respect to FIGS. 12-14.

Referring now to FIG. 8, therein is shown the first step 800 of an alternative process. The alternative process has the advantage over the first process (shown in FIGS. 6 and 7) of providing a reduced process procedure and of enabling the die attach adhesives to be cured together at the same time.

Thus, as shown in FIG. 8, the PAA 602 is laminated to the board 502.

Referring now to FIG. 9, therein is shown a cross-sectional view of the structure of FIG. 4 following application of the film adhesive 702 to one of the chips 402.

Referring now to FIG. 10, therein is shown the structure of FIG. 9, following retrieval of a chip 302 from the wafer 300 (FIG. 3) by a vacuum picker 1002. After retrieval, the vacuum picker 1002 has applied the chip 302 face up to the film adhesive 702 on the back of the chip 402. The sandwich of the chip 302, the film adhesive 702, and the chip 402 has then been lifted (as shown in FIG. 10) by the vacuum picker 1002 from the wafer mount tape 404 for transportation to the PAA 602 on the board 502 (see FIG. 11). The chip 302 is upright or face up; the chip 402 is inverted or face down.

Referring now to FIG. 11, therein is shown the structure of FIG. 8 following transportation thereto by the vacuum picker 1002 (FIG. 10) of the sandwiched chips 302 and 402 (FIG. 10). The film adhesive 702 and the PAA 602 are then simultaneously cured, and will have the characteristics of having been simultaneously cured inasmuch as they will have received the same (equal) curing treatment.

Referring now to FIG. 12, therein is shown a first wire attach stage 1200 for the structures shown in FIGS. 7 and 11. The structures have been inverted, and electrical conductors such as bonding wires 1202 have been attached to electrically connect the bottom bonding pads 506 to bonding pads 1204 on the chip 402. This bonding process may be conveniently facilitated by a suitable fixture such as a fixture 1206.

Referring now to FIG. 13, therein is shown a second wire attach stage 1300 in which the board 502 and attached chips 302 and 402 of FIG. 12 have been again inverted onto a suitable fixture 1302. Additional electrical conductors such as bonding wires 1304 are then electrically connected between the top bonding pads 504 and bonding pads 1306 on the chip

Referring now to FIG. 14, therein is shown the structure of FIG. 13 formed into a package 1400 by encapsulation in an encapsulant 1402, the encapsulant 1402 also forming the lower encapsulation portion 204. Solder balls 202 have been attached to the bottom of the board 502 to provide, for example, a BGA configuration. The solder balls 202 provide external electrical connections for the board 502 on the bottom side thereof opposite the chips 302 and 402.

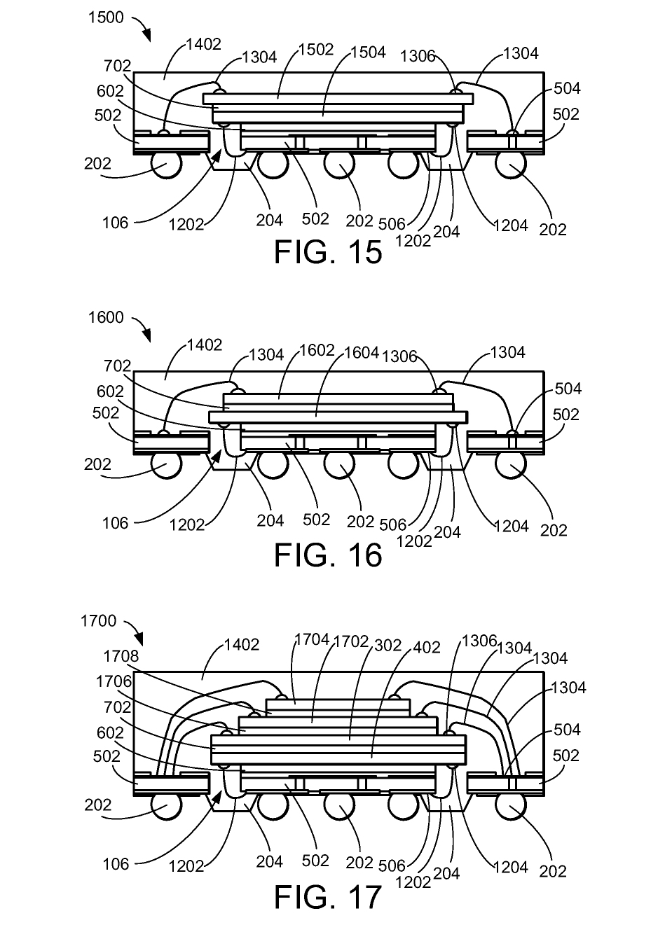

Referring now to FIG. 15, therein is shown a package 1500 similar to the package 1400 (FIG. 14) except that an upper chip 1502 has been employed that is larger than a lower chip 1504 therebeneath.

Referring now to FIG. 16, therein is shown a package 1600 similar to the package 1400 (FIG. 14) and the package 1500 (FIG. 15) except that an upper chip 1602 has been employed that is smaller than a lower chip 1604 therebeneath.

Referring now to FIG. 17, therein is shown a package 1700 similar to the package 1400 (FIG. 14) except that additional chips such as a third chip 1702 and a fourth chip 1704, of progressively smaller sizes respectively, have been mounted on top of the chips 402 and 302, in face up positions, and secured by respective adhesive layers 1706 and 1708.

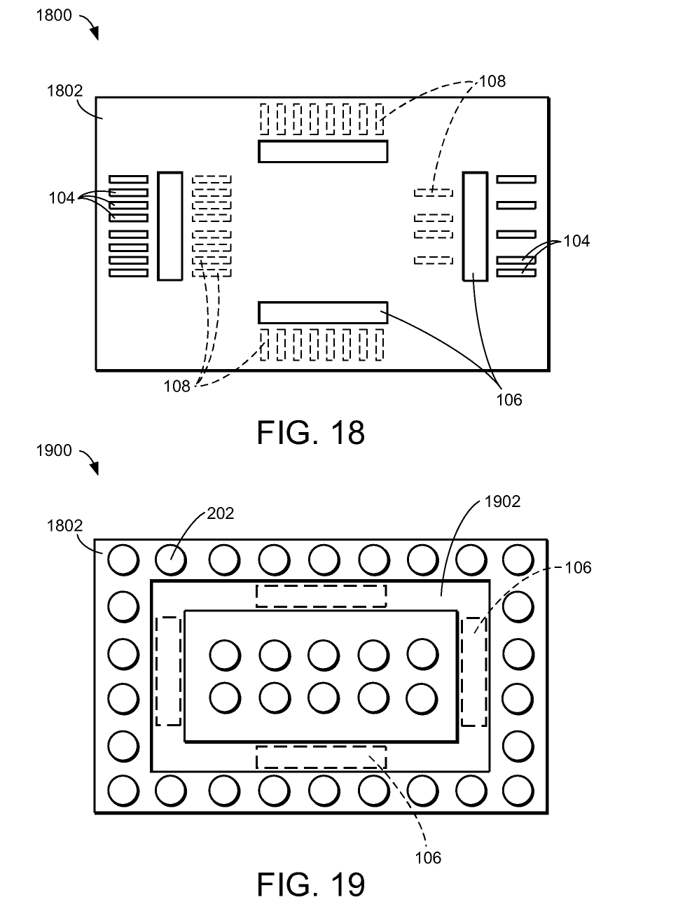

Referring now to FIG. 18, therein is shown a substrate 1800 similar to the substrate 100 (FIG. 1) except that the substrate 1800 has a board 1802 that has four windows 106 therethrough for accommodating a first chip thereon, face down, similarly as the chip 402 is applied (see FIG. 13). The substrate 1800 thus has bonding pads along all four sides of the bottom thereof. The four windows 106 then provide access along all four sides of a first chip (not shown), through the windows 106, to the bottom bonding pads 108 on the bottom of the board 1802.

Referring now to FIG. 19, therein is shown a bottom view of a package 1900 formed using the substrate 1800 (FIG. 18). Solder balls 202 are attached to the bottom of the package 1900 in a ball grid array (“BGA”) configuration, and it will be understood that a pin grid array (“PGA”) may similarly be provided on the bottom of the package 1900. The windows 106 have been sealed and encapsulated in a lower encapsulation portion 1902 similar to that illustrated, for example, in FIG. 14.

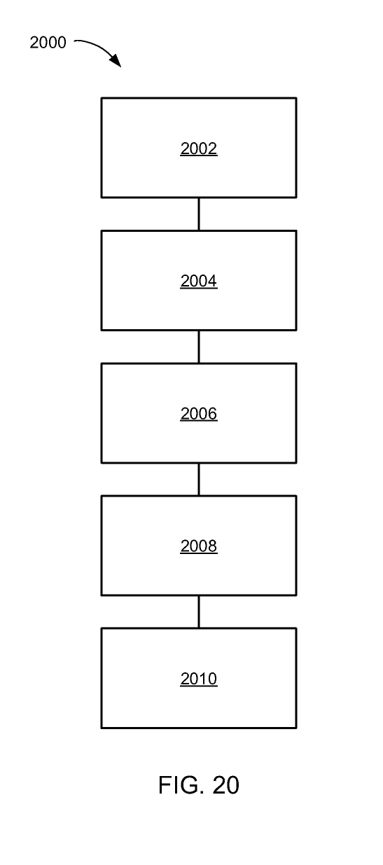

Referring now to FIG. 20, therein is shown a flow chart of a system 2000 for spacerless semiconductor package chip stacking in accordance with an embodiment of the present invention. The system 2000 includes providing a substrate having at least one window therethrough in a block 2002; attaching a first semiconductor device face down on the top of the substrate in a block 2004; attaching a second semiconductor device face up on the back of the first semiconductor device in a block 2006; electrically connecting the first semiconductor device through the window to the bottom of the substrate in a block 2008; and electrically connecting the second semiconductor device to the substrate in a block 2010.

It has been unexpectedly discovered that the present invention thus has numerous aspects.

A principle aspect that has been unexpectedly discovered is that the present invention provides particularly thin, stacked, multi-chip module (“MCM”) configurations that readily accommodate standard semiconductor chips and devices.

Another aspect is that the present invention accomplishes such thin packages efficiently and economically, providing fast and stable process flows.

Another important aspect is that the thin, lower package profiles of the present invention can be provided for semiconductor devices that have similar or identical sizes, since the need for bonding wire clearances between them has been eliminated.

Yet another important aspect of the present invention is that it valuably supports and services the historical trend of reducing costs, simplifying systems, and increasing performance.

These and other valuable aspects of the present invention consequently further the state of the technology to at least the next level.

Thus, it has been discovered that the spacerless semiconductor package chip stacking system of the present invention furnishes important and heretofore unknown and unavailable solutions, capabilities, and functional aspects for MCM packaging. The resulting processes and configurations are straightforward, cost-effective, uncomplicated, highly versatile and effective, can be surprisingly and unobviously implemented by adapting known technologies, and are thus readily suited for efficiently and economically manufacturing thin MCM packages.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters hithertofore set forth herein or shown in the accompanying drawings are to be interpreted in an illustrative and non-limiting sense.

What is claimed is:

1. A spacerless semiconductor package chip stacking system, comprising:
providing a substrate having at least one window therethrough;
attaching a first semiconductor device face down on the top of the substrate;
attaching a second semiconductor device face up on the back of the first semiconductor device;
electrically connecting the first semiconductor device through the window to the bottom of the substrate; and
electrically connecting the second semiconductor device to the substrate.

2. The system as claimed in claim 1 further comprising attaching the first and second semiconductor devices to one another prior to attaching the first semiconductor device to the substrate.

3. The system as claimed in claim 1 further comprising providing external electrical connections for the substrate on the bottom side thereof opposite the semiconductor devices.

4. The system as claimed in claim 1 in which the first and second semiconductor devices are substantially the same size.

5. The system as claimed in claim 1:
in which attaching a second semiconductor device face up on the back of the first semiconductor device further comprises attaching the semiconductor devices to one another with an adhesive;
in which attaching a first semiconductor device face down on the top of the substrate further comprises attaching the first semiconductor device to the substrate with an adhesive; and
further comprising curing the adhesives simultaneously.

6. A spacerless semiconductor package chip stacking system, comprising:
providing a substrate having at least one window therethrough;
attaching a first semiconductor device face down with a film adhesive or a pre-applied adhesive on the top of the substrate;
attaching a second semiconductor device face up with a film adhesive or a pre-applied adhesive on the back of the first semiconductor device;
electrically connecting the first semiconductor device through the window to the bottom of the substrate;
electrically connecting the second semiconductor device to the substrate;
sealing and encapsulating the window in a lower encapsulation portion; and
encapsulating the semiconductor devices and at least a portion of the substrate.

7. The system as claimed in claim 6 further comprising attaching the first and second semiconductor devices to one another prior to attaching the first semiconductor device to the substrate.

8. The system as claimed in claim 6 further comprising providing external ball grid array or pin grid array electrical connections for the substrate on the bottom side thereof opposite the semiconductor devices.

9. The system as claimed in claim 6 in which the first and second semiconductor devices are the same size.

10. The system as claimed in claim 6 further comprising curing the adhesives simultaneously.

11. A spacerless semiconductor package chip stacking system, comprising:
a substrate having at least one window therethrough;
a first semiconductor device attached face down on the top of the substrate;
a second semiconductor device attached face up on the back of the first semiconductor device;
conductors electrically connecting the first semiconductor device through the window to the bottom of the substrate; and
conductors electrically connecting the second semiconductor device to the substrate.

12. The system as claimed in claim 11 in which the first and second semiconductor devices are substantially the same size.

13. The system as claimed in claim 11 in which the first and second semiconductor devices are of different sizes.

14. The system as claimed in claim 11 further comprising external electrical connections for the substrate on the bottom side thereof opposite the semiconductor devices.

15. The system as claimed in claim 11 further comprising:
an adhesive attaching the semiconductor devices to one another;
an adhesive attaching the first semiconductor device to the substrate; and
the adhesives having the characteristics of having been cured simultaneously.

16. The system as claimed in claim 11:
in which the conductors are bonding wires; and
further comprising:
a film adhesive or a pre-applied adhesive attaching the first semiconductor device on the substrate;
a film adhesive or a pre-applied adhesive attaching the second semiconductor device on the first semiconductor device;
a lower encapsulation portion sealing and encapsulating the window; and
an encapsulant encapsulating the semiconductor devices and at least a portion of the substrate.

17. The system as claimed in claim 16 in which the first and second semiconductor devices are the same size.

18. The system as claimed in claim 16 in which the first and second semiconductor devices are of different sizes.

19. The system as claimed in claim 16 further comprising external ball grid array or pin grid array electrical connections for the substrate on the bottom side thereof opposite the semiconductor devices.

20. The system as claimed in claim 16 in which the adhesives further comprise adhesives that have the characteristics of having been cured simultaneously.
